(19) United States
(12) Patent Application Publication
(10) Pub. No.: US 2011/0148477 A1
(43) Pub. Date: Jun. 23, 2011

(54) SIGNAL TRANSMISSION DEVICE

(76) Inventors: Kohei Teramoto, Tokyo (JP); Tsuyoshi Nakada, Tokyo (JP); Kazuhiko Hashimoto, Tokyo (JP); Hajime Koyama, Tokyo (JP); Koji Tsukamoto, Tokyo (JP); Yoshihiko Mori, Tokyo (JP)

(21) Appl. No.: 13/062,269

(22) PCT Filed: Sep. 30, 2009
(86) PCT No.: PCT/JP2009/005037

§ 371 Date: Mar. 4, 2011

(30) Foreign Application Priority Data
Nov. 28, 2008 (JP) 2008-303675

(51) Int. Cl. H03K 19/0175

(52) U.S. Cl. 327/109

(57) ABSTRACT

A signal transmission device includes a transmitting circuit 11 and a receiving circuit 12 provided with shunt regulator power supplies 110 and 120 for causing fixed currents to flow thereinto respectively, and a signal transmission path 13 connecting between the transmitting circuit 11 and the receiving circuit 12 and having a function of preventing an alternating current component, in which a ground GND_{A} of the transmitting circuit 11 and a ground GND_{B} of the receiving circuit 12 are disposed independently of each other, and are connected to a ground GND_{C} of the shunt regulator power supplies 110 and 120 at a single point.

### FIELD OF THE INVENTION

The present invention relates to a signal transmission device in which a transmitting circuit and a receiving circuit are connected via a signal transmission path.

### BACKGROUND OF THE INVENTION

For each of logic signals for use with serial interfaces, such as an EIA232 interface and an IEEE 1284 interface, TTL, MOS, and so on, and for each of many types of analog signals, a single signal line is used, and each signal is sent in the form of a voltage against the ground of the signal.

This signal transmission method is called unbalanced transmission, and the signal is called a single end.

On the other hand, for each signal for use with a digital interface used for communication equipment or flat-panel display connection, such as a 100 Base-T interface or an LVDS (Low Voltage Differential Signal) interface, a pair of two equal signal lines is used, and each signal is sent in the form of a potential difference between the signal lines of the pair.

This signal transmission method is called balanced transmission, and the signal is called a differential signal.

### SUMMARY OF THE INVENTION

By the way, efforts to pursue sound quality and performance in the field of development of digital audio equipment represented by a CD (Compact Disc) player have continued without letup.

For example, in a case in which a transmitting circuit 31 which consists of a digital signal processing circuit or the like, and a receiving circuit 32 which consists of a DA (Digital Analog) conversion circuit or the like are mounted on the same board, as shown in FIG. 2, when a digital noise (an alternating current signal component) caused by the transmitting circuit 31 mixes into the receiving circuit or an analog circuit connected behind the receiving circuit 32 after propagating through a signal line 33, power source lines 34, and a ground line 35, degradation occurs in the SN ratio (Signal to Noise Rate) and distortion rate of an analog signal, and, as a result, the sound quality degrades.

In FIG. 2, power supply circuits 36 and 37 supply power to the transmitting circuit 31 and the receiving circuit 32 respectively.

On the other hand, there is a case in which a signal line 33 is isolated by using a photo coupler 40 or the like in order to remove a digital noise and a jitter which are included in an input signal, as shown in FIG. 3. Even in this case, because a loop is still formed between a transmitting circuit 31 and a receiving circuit 32 via power source lines 34 and a ground line 35, a digital noise including a jitter propagates, and this results in degradation of the sound quality.

The present invention is made in order to solve the above-mentioned problems, and it is therefore an object of the present invention to provide a signal transmission device that prevents a digital noise other than a signal component outputted from a transmitting circuit from mixing into a receiving circuit via a signal line, power source lines, and a ground line.

In order to solve the above-mentioned problems, in accordance with the present invention, there is provided a signal transmission device including: a transmitting circuit and a receiving circuit provided with shunt-type power supplies for causing fixed currents to flow thereinto respectively; and a signal transmission path connecting between the transmitting circuit and the receiving circuit and having a function of preventing an alternating current component, in which a ground of the transmitting circuit and a ground of the receiving circuit are disposed independently of each other, and are connected to a ground of the shunt-type power supplies at a single point.

According to the present invention, because the ground of the transmitting circuit and the ground of the receiving circuit are disposed independently of each other, and are connected to the ground of the shunt-type power supplies at the single point, no current flows into a loop formed of the signal transmission path and the grounds of the transmitting circuit and the receiving circuit which are connected to the ground of the shunt-type power supplies at the single point. Therefore, the ground potential of the ground of the transmitting circuit and that of the receiving circuit are maintained constant, and the signal transmission device can prevent a digital noise other than a signal component outputted from the transmitting circuit from mixing into the receiving circuit of via a signal line, a power source lines and a ground line.

### BRIEF DESCRIPTION OF THE FIGURES

FIG. 1 is a block diagram showing the circuit structure of a signal transmission device in accordance with Embodiment 1 of the present invention;

FIG. 2 is a view showing the circuit structure of an example of a conventional signal transmission device; and

FIG. 3 is a view showing the circuit structure of another example of the conventional signal transmission device.

### EMBODIMENTS OF THE INVENTION

Hereafter, in order to explain this invention in greater detail, the preferred embodiments of the present invention will be described with reference to the accompanying drawings.

### Embodiment 1

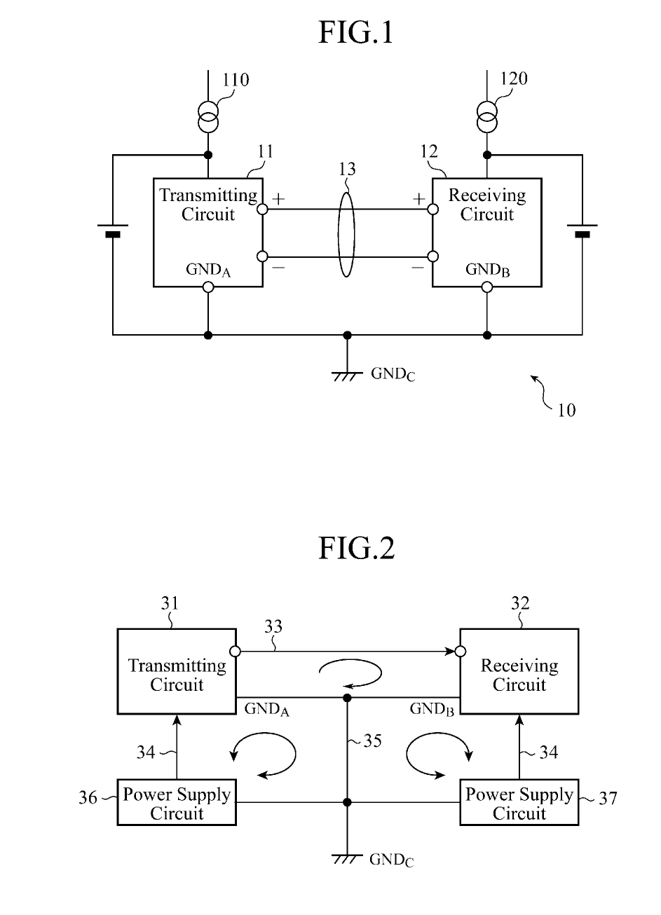

FIG. 1 is a block diagram showing the circuit structure of a signal transmission device in accordance with Embodiment 1 of the present invention. As shown in FIG. 1, the signal transmission device 10 in accordance with Embodiment 1 of the present invention is comprised of a transmitting circuit 11 and a receiving circuit 12. These transmitting circuit 11 and receiving circuit 12 are provided with shunt regulator power supplies (shunt-type power supplies) 110 and 120 for causing fixed currents to flow into the transmitting circuit and the receiving circuit independently respectively.

The transmitting circuit 11 is a digital signal processing circuit, for example, the receiving circuit 12 is a DA conversion circuit, for example, and these circuits are connected to each other via a signal transmission path 13.

In this embodiment, in order to prevent an alternating current signal component from flowing from the transmitting circuit 11 into the receiving circuit 12 via the signal transmission path 13, balanced transmission is used as a signal transmission method.

As known well, the balanced transmission is a method of using a pair of two equal signal lines for one signal flowing through the signal transmission path 13, and transmitting the signal in the form of a potential difference between the signal lines of the pair.

Concretely, as shown in FIG. 1, the transmitting circuit 11 transmits a signal of opposite phase between a cold signal line (−) and a ground (GND_{A}) with respect to a signal transmitted between a hot signal line (+) and the ground (GND_{A}). The receiving circuit 12 is thus constructed in such a way as to remove an extraneous noise between the hot signal line (+) and the cold signal line (−) by using a not-shown differential receiver.

Furthermore, the signal transmission device in accordance with Embodiment 1 of the present invention is constructed in such a way that the ground (GND_{A}) of the transmitting circuit 11 and the ground (GND_{B}) of the receiving circuit 12 are disposed independently of each other, and are connected in common to a single point of a ground (GND_{C}) of the shunt regulator power supplies 110 and 120.

With the above-mentioned structure, the shunt regulator power supplies 110 and 120 supply power to the transmitting circuit 11 and the receiving circuit 12 independently of each other, respectively. At this time, the power sources cause fixed currents to flow into the transmitting circuit and the receiving circuit respectively. At that time, the currents having fixed values flow into the transmitting circuit 11 and the receiving circuit 12 from the shunt regulator power supplies 110 and 120 respectively, and a current flowing into the ground (GND_{C}) at the single point via the grounds (GND_{A} and GND_{B}) from the transmitting circuit 11 and the receiving circuit 12 has also a fixed value. As a result, the potential of each of the grounds (GND_{A} and GND_{B}) of the transmitting circuit 11 and the receiving circuit 12 is maintained constant.

Furthermore, because a signal flowing through the signal transmission path 13 has a fixed current value through the use of the balanced transmission as the signal transmission method of transmitting the signal between the transmitting circuit 11 and the receiving circuit 12, no alternating current flows into the loop formed of the signal transmission path 13 and the grounds (GND_{A} and GND_{B}) of the transmitting circuit 11 and the receiving circuit 12 which are connected to the power supply GND_{C}.

As mentioned above, as the result of preventing an alternating current from flowing into and from any of the signal line (the signal transmission path 13), the power source lines and the ground line, variations in the potential of each of the grounds (GND_{A} and GND_{B}) of the transmitting circuit 11 and the receiving circuit 12 can be prevented. Therefore, the potential of each of the grounds (GND_{A} and GND_{B}) is stabilized, and a digital noise, such as a jitter, occurring at the time of the transmission of the signal can be prevented from propagating.

Because in the above-mentioned signal transmission device in accordance with Embodiment 1 of the present invention, the transmitting circuit 11 and the receiving circuit 12 are independently provided with the shunt regulator power supplies 110 and 120, respectively, the values of the currents supplied to the transmitting circuit 11 and the receiving circuit 12 become fixed with respect to the power supplies, and the values of the currents respectively flowing into the grounds (GND_{A} and GND_{B}) from the transmitting circuit 11 and the receiving circuit 12 are also maintained constant.

Furthermore, because the balanced transmission is used as the signal transmission method of transmitting a signal from the transmitting circuit 11 to the receiving circuit 12, and the grounds (GND_{A} and GND_{B}) of the transmitting circuit 11 and the receiving circuit 12 are disposed independently of each other and are connected to the ground (GND_{C}) at the single point, the value of the current furnished from the transmitting circuit 11 to the receiving circuit 12 becomes fixed while no alternating current flows into the loop formed of the signal transmission path 13 and the grounds (GND_{A} and GND_{B}) of the transmitting circuit 11 and the receiving circuit 12 which are connected to the ground GND_{C}.

As mentioned above, the signal transmission device in accordance with Embodiment 1 of the present invention can prevent variations in the ground potentials of the transmitting circuit 11 and the receiving circuit 12 as the result of preventing an alternating current from flowing into and from any of the signal line, the power source lines and the ground line. Therefore, the potential of each of the grounds is stabilized, and a digital noise, such as a jitter, occurring at the time of the transmission of the signal can be prevented from propagating. Furthermore, the occurrence of a jitter caused by time-dependent variations in the threshold level of the digital circuit occurring due to variations in the potential between the grounds can also be suppressed.

Particularly, by applying the signal transmission device in accordance with Embodiment 1 of the present invention to the field of digital audio in which mixing of a digital noise has an influence on the sound quality and performance remarkably, significant advantages can be provided.

### Embodiment 2

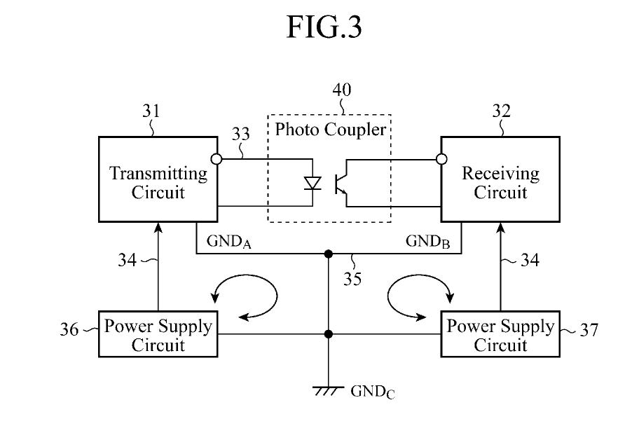

The above-mentioned signal transmission device in accordance with Embodiment 1 prevents an alternating current signal component from flowing from the transmitting circuit 11 into the receiving circuit 12 via the signal transmission path 13 by using one pair of two equal signal lines for one signal flowing through the signal transmission path 13 for transmission of a signal from the transmitting circuit 11 to the receiving circuit 12, and transmitting the signal in the form of a potential difference between the signal lines of the pair. As an alternative, by using electrical isolation provided by a photo coupler 40 shown in FIG. 3, for example, instead of the above-mentioned balanced transmission, an alternating current signal component can be prevented from flowing from the transmitting circuit 11 into the receiving circuit 12 via the signal transmission path 13. Even in this case, the same advantages can be provided. Furthermore, a pulse transformer can be used instead of the photo coupler 40.

In the above-mentioned signal transmission device in accordance with Embodiment 2, fixed currents flow into the transmitting circuit 11 and the receiving circuit 12 from the shunt regulator power supplies 110 and 120 which are mounted in the transmitting circuit 11 and the receiving circuit 12, respectively, and a current flowing into the ground (GND_{C}) at the single point via the grounds (GND_{A} and GND_{B}) from the transmitting circuit 11 and the receiving circuit 12 has also a fixed value, like in the case of that according to Embodiment 1. As a result, the potential of each of the grounds (GND_{A} and GND_{B}) of the transmitting circuit 11 and the receiving circuit 12 is maintained constant.

In addition, because the transmission of a signal between the transmitting circuit 11 and the receiving circuit 12 has also a constant current by virtue of the isolation by the photo coupler 40 or the like, no current flows into the loop formed of the signal transmission path 13 and the grounds (GND_{A} and GND_{B}) of the transmitting circuit 11 and the receiving circuit 12 which are connected to the ground GND_{C} at the single point. As a result, the ground potentials of the transmitting circuit 11 and the receiving circuit 12 are maintained constant, and the propagation of a digital noise through the signal line, the power source lines and the ground line due to current variations can be eliminated.

In the above explanation, only the case in which the signal transmission device in accordance with any of Embodiments 1 and 2 of the present invention is applied to audio equipment is shown. The applicability of the present invention is not limited to audio equipment, and the present invention can be applied to any electronic equipment equipped with a digital interface used for communication equipment or flat-panel display connection, such as a 100 Base-T interface, an ETA485 interface, or an LVDS interface.

### INDUSTRIAL APPLICABILITY

Because the signal transmission device in accordance with the present invention can prevent a digital noise other than a signal component outputted from the transmitting circuit from mixing into the receiving circuit of via the signal line, the power source lines and ground line, the signal transmission device in accordance with the present invention is suitable for use as a signal transmission device in which a transmitting circuit and a receiving circuit are connected to each other via a signal transmission path, or the like.

1. A signal transmission device comprising:
a transmitting circuit and a receiving circuit provided with shunt-type power supplies for causing fixed currents to flow thereinto respectively; and
a signal transmission path connecting between said transmitting circuit and said receiving circuit and having a function of preventing an alternating current component, wherein
a ground of said transmitting circuit and a ground of said receiving circuit are disposed independently of each other, and are connected to a ground of said shunt-type power supplies at a single point.

2. The signal transmission device according to claim 1, wherein said signal transmission path is a balanced differential signal transmission circuit which uses a pair of two equal signal lines for one signal to transmit said signal in a form of a potential difference between said signal lines of the pair.

3. The signal transmission device according to claim 1, wherein said signal transmission path has a photo coupler.
